(19) United States
(12) Patent Application Publication
(10) Pub. No.: US 2011/0155992 A1
(43) Pub. Date: Jun. 30, 2011

(54) PHASE-SEPARATION TYPE PHASE-CHANGE MEMORY

(75) Inventors: Chin Fu Kao, Taipei City (TW); Tsung Shune Chin, Hsinchu County (TW); Frederick Ta Chen, Hsinchu County (TW); Ming Jinn Tsai, Hsinchu City (TW)

(73) Assignees: Industrial Technology Research Institute, Hsinchu (TW); National Tsing Hua University, Hsinchu (TW); Feng Chia University, Taichung City (TW)

(21) Appl. No.: 12/774,413

(22) Filed: May 5, 2010

(30) Foreign Application Priority Data
Dec. 30, 2009 (TW) 098146013

(51) Int. Cl. H01L 45/00

(52) U.S. Cl. 257/4; 257/E45.002

(57) ABSTRACT

A eutectic memory includes a eutectic memory material layer, a top and a bottom electrodes, or a left and a right electrodes. Materials of the eutectic memory layer are represented by M₁-M₂-X wherein the M₁ is a semiconductor element, the M₂ is a metallic element which forms eutectic with the M₁, and the X is an unavoidable impurity or an added element.

### CROSS-REFERENCE TO RELATED APPLICATIONS

This non-provisional application claims priority under 35 U.S.C. §119(a) on Patent Application No(s). 098146013 filed in Taiwan, R.O.C. on Dec. 30, 2009, the entire contents of which are hereby incorporated by reference.

### BACKGROUND

1. Field of Invention

The present disclosure relates to an electronic memory which is non-volatile able to keep stored information upon interruption of electric power. Specifically the present disclosure involves a phase-change type non-volatile memory in which the phase-change material undergoes a eutectic type phase-separation accompanies with the phase changes. Most specifically this disclosure is a phase-separation type phase-change memory.

2. Related Art

A non-volatile memory (NVM) is a type of memory data in it do not disappear when power supplied to the memory is turned off and can be stored unless being erased. Therefore, similar to a hard disk, the NVM can be regarded as an element for storing information permanently. The NVM is widely applied in various fields, especially in mobile products such as in a mobile phone, a digital camera, an MP3 player, a personal computer, a notebook computer and so on.

A volatile memory (VM) is opposite to the NVM. Most popular VMs are a dynamic random-access-memory (DRAM) and a static random-access-memory (SRAM), which can be written and read randomly with a high speed (usually around 30-40 ns). Therefore, the VM is usually used as a temporary data storage medium for a computer, a computational processing system, other programming or data being executed. However, when power is removed from the non-volatile random-access-memories (DRAM and SRAM), the data stored therein disappear, that is, volatilized.

Therefore, it becomes an important subject in the memory development to find a new memory having both a storage function of the hard disk and a rapid access speed of a random-access-memory.

Various non-volatile memory mechanisms/devices have been rigorously researched in recently years. Taking for example, a magnetoresistive random-access-memory (MRAM), a ferroelectric random-access-memory (FeRAM), a conductive bridge random-access-memory (CBRAM), a resistive random-access-memory (RRAM), and a phase-change random-access-memory (PRAM), are emerging data storage devices for future application.

Among the new types of non-volatile memories, PRAM utilizes phase-change of a material as a storage element. The phase-change material has at least two different solid states, that is, an amorphous state and a corresponding crystalline state, keeping the composition unchanged before and after phase-change. The phase-change material can be rapidly and reversibly switched between the two different states through a very rapid change of temperature. The amorphous state and crystalline state possess substantial difference in electrical resistance, which is usually up to ten thousand times even to a million times, to represent a digital “1” or a digital “0” and stored in the PRAM to be read by using a reading pulse with smaller voltage or current.

However, the PRAM usually makes use of chalcogenides (compounds containing Se or/and Te as the major components), for example, doped Ge₂Sb₂Te₅ or doped SbTe compounds as the phase change materials. The material can be melted at a temperature higher than the melting point which is usually higher than 600° C. And after fast solidification, the material becomes an amorphous state with the same composition. Whereas, the amorphous state can be switched back to the crystalline state by a mild heating to a temperature higher than the crystallization temperature, which is usually lower than 200° C. The attainment of such high temperatures requires large current which also causes great temperature rise around the memory unit, thus reducing the reliability. Besides, the crystalline single phase of the benchmark Ge₂Sb₂Te₅ only existed in a narrow region in Ge—Sb—Te ternary phase-diagram which contained many other single phases with a fixed composition such as Ge₁Sb₂Te₄ and Ge₁Sb₄Te₇ along the tie-line GeTe—Sb₂Te₃. Repetitive reversing the states of memory units for a great number of times as in the case of long term read-write operation for more than tens of million times, the composition of the phase-change material is susceptible to alter unavoidably, thus causing variations in the physical properties of the material. The changes in the physical characteristics also directly influence the operation parameters of the memory. Therefore, it is a big challenge for conventional phase-change materials for cycling switches under a great number of times without any variation in composition. Moreover, the chalcogenides used in the conventional phase-change memory have a low crystallization temperature, usually between 160° C. and 180° C., which varies slightly according to modification of composition. So that the PRAM is operative only at room temperature, and the archival temperature, defined as the temperature at which information can be stored therein safely for ten years, is difficult to satisfy the basic requirement of 100° C. Furthermore, the chalcogenides are not only difficult to be integrated with the front-end of line IC fabrication process, but also cause serious pollution problems to the environment.

### SUMMARY

Accordingly, the present disclosure proposes a phase-separation type memory, or eutectic memory, or so as to solve the above problems.

The present disclosure provides a eutectic memory, which comprises a eutectic memory layer. Representative material of the eutectic memory layer is a combination of elements M₁-M₂-X. The M₁-M₂ is a eutectic alloy system, M₁ is at least one element selected from germanium, silicon, and carbon; M₂ is a metallic element used in daily IC process, and the X is an unavoidable impurity or an added element to adjust physical properties.

The present disclosure further provides a eutectic memory device which comprises a eutectic memory layer and a pair of electrodes. The eutectic memory device is able to heat the memory layer to a first temperature and quenched to form an amorphous state. The device is also able to heat the amorphous state to a second temperature to induce a phase-separated crystalline state.

The eutectic memory layer is located between the pair of electrode layers. When the eutectic memory layer is heated to a first temperature by the pair of electrode layers and then cooled to an amorphous state, the eutectic memory amorphous layer has a first resistance. When the eutectic memory amorphous layer is heated to a second temperature by the pair of electrode layers and cooled to a phase-separated crystalline state, the eutectic memory layer has a second resistance. The difference between the first resistance and the second resistance is more than one order of magnitude.

The eutectic memory presented in this disclosure provides a solution to overcome those problems mentioned in the previous section. The first priority in materials design is to make use of elements compatible to the front-end-of-line integration circuits. The second is to achieve excellent performance in thermal stability, and aiming to achieve high temperature operative NVM at 100° C. and higher. In the meantime, all the materials used will not pollute our environment and be friendly to the production surroundings. The most commonly used elements in the integrated circuits are silicon, germanium, copper, and aluminum. The present disclosure starts with and extends from a combination of the four elements. It is unavoidable to face the problem of phase-separation during “eutectic” transformation instead of the single phase-change, for example, in Si—Al, Ge—Al, Si—Cu and Ge—Cu material systems. The present disclosure aims to overcome the difficulties arisen from phase-separation, thus to developing the novel eutectic memory.

### BRIEF DESCRIPTION OF THE DRAWINGS

The present disclosure will become more fully understood from the detailed description given herein below for illustration only, and thus are not limitative of the present disclosure, and wherein:

FIG. 1 is a eutectic diagram of aluminum-germanium according to the present disclosure;

FIG. 2 shows the curve of electrical resistance versus temperature showing a sudden decrease in resistance upon eutectic crystallization;

FIG. 3 is a schematic diagram showing cross-section of a eutectic memory testing cell according to an embodiment of the present disclosure;

FIG. 4 is a schematic diagram showing cross-section of an eutectic memory testing cell employing lateral cell architecture according to the present disclosure;

FIG. 5 is a schematic diagram showing the curves of the programming temperature dependent on the programming parameters according to the present disclosure;

FIG. 6A is diagram showing electrical resistance dependent on applied currents of a eutectic memory testing cell (operated at room temperature) according to a first embodiment of the present disclosure;

FIG. 6B is diagram showing electrical resistance dependent on applied current of a eutectic memory testing cell (operated at 160° C.) according to the first embodiment of the present disclosure;

FIG. 7 is a cycling test result of a eutectic memory testing cell, showing the capability of more than ten million times of operation (operated at room temperature) according to a third embodiment of the present disclosure;

FIG. 8 is a cycling test result of a eutectic memory testing cell, showing the capability of more than three million times of operation (operated at 160° C.) according to a fourth embodiment of the present disclosure;

FIG. 9 shows the data retention of a Ge₆₁Al₃₉ film extrapolated from the short-term time-to-failure study, the X axis is reciprocals temperature (in degree Kelvin) and the Y axis is the time-to-failure according to the fourth embodiment of the present disclosure;

FIG. 10 is a diagram showing electrical resistance versus temperature obtained from silicon added Ge₆Al₃₉ thin films according to a fifth embodiment of the present disclosure, and the value behind each element is the sputtering power (in Watt) for each target;

FIG. 11 is a diagram showing electrical resistance versus temperature obtained from SiO₂ doped Ge₇₀Al₃₀ thin films according to a sixth embodiment of the present disclosure, and the sputtering power of the Ge, Al, and SiO₂ is 100 W, 40 W, and 100 W respectively;

FIG. 12 is a resistance-temperature diagram obtained from carbon doped Ge₇₀Al₃₀ thin films according to a seventh embodiment of the present disclosure, and values behind the Ge+Al+C represent sputtering wattage of each element respectively;

FIG. 13 is a resistance-temperature diagram obtained from the boron doped Ge₇₀Al₃₀ thin films according to an eighth embodiment of the present disclosure, and values behind the Ge₇₀Al₃₀+B represent sputtering wattage of the Ge₇₀Al₃₀ target and the boron target;

FIG. 14 is a resistance-temperature diagram obtained from the nitrogen doped Ge₇₀Al₃₀ thin films by reactive sputtering with nitrogen gas according to a ninth embodiment of the present disclosure, and the flow rate of nitrogen gas is shown in lower left corner;

FIG. 15 is a resistance-temperature diagram obtained from the cupper doped Ge₇₀Al₃₀ thin films by co-sputtering with Ge₇₀Al₃₀ alloy target and copper target according to a tenth embodiment of the present disclosure, and values behind Ge₇₀Al₃₀+Cu represent sputtering wattage of the Ge₇₀Al₃₀ target and the copper target;

FIG. 16 is a resistance-temperature diagram obtained from the titanium doped Ge₇₀Al₃₀ thin films by co-sputtering Ge₇₀Al₃₀ alloy target and titanium target according to an eleventh embodiment of the present disclosure, and values behind Ge₇₀Al₃₀+Ti represent sputtering wattage of the Ge₇₀Al₃₀ target and the titanium target;

FIG. 17 is a resistance-temperature diagram obtained from the Geranium-Tin thin films by co-sputtering targets of geranium and tin according to a twelfth embodiment of the present disclosure;

FIG. 18 is a resistance-temperature diagram of germanium-copper thin films according to a thirteenth embodiment of the present disclosure;

FIG. 19 is a resistance-voltage diagram showing the electrical characteristics of a germanium-copper (Ge₉₆Cu₄) test cell under a pulse-width 10 ns according to a fourteenth embodiment of the present disclosure;

FIG. 20 is a resistance-voltage diagram showing the electrical characteristics of a germanium-aluminum-copper test-cell under a pulse-width 5 ns according to a fifteenth embodiment of the present disclosure;

FIG. 21 is a resistance-temperature diagram obtained from the Si—Al thin films by co-sputtering silicon and aluminum targets according to a sixteenth embodiment of the present disclosure, and values behind Si—Al in the small box represent sputtering wattage of the silicon target and the aluminum target; and

FIG. 22 is a resistance-temperature diagram obtained from the C—Sb thin films by co-sputtering carbon and antinomy targets according to a seventeenth embodiment of the present disclosure, and values behind C:Sb in the small box represent sputtering wattage of the carbon target and the antimony target.

### DETAILED DESCRIPTION

The above description of the contents of the present disclosure and the illustration of the following detailed description are used to exemplify and explain the spirit and principles of the present disclosure, so as to provide further explanation of the claims of the present disclosure.

The detailed features and advantages of the present disclosure are illustrated in the detailed description below, the contents of which are sufficient for any person skilled in the art to understand and implement the technical contents of the present disclosure. Also, according to the contents, claims, and accompanying drawings disclosed in the specification, any person skilled in the art can easily understand the related objectives and advantages of the present disclosure. The following embodiments are used to further illustrate the viewpoint of the present disclosure in detail, instead of limiting the scope of the present disclosure.

The present disclosure provides a eutectic memory, which comprises a eutectic memory layer. The material of the eutectic memory layer is represented by the elements M₁-M₂-X. The M₁-M₂ is a eutectic alloy system, and the X is an unavoidable impurity or an added element. The M₁ is at least one element selected from germanium, silicon, and carbon. That is to say, the eutectic memory layer is a eutectic alloy mainly containing germanium, silicon or/and carbon.

For the selection of material systems under the above design principles, the M₁ is most preferably silicon and germanium daily used in the front-end-of-line of the integrated circuit industry, and carbon of the same group in the periodic table as also being used in nowadays high speed integrated circuits. The M₂ is most preferably aluminum, copper, titanium, tantalum, tungsten which are most commonly used in the front-end-of-line processing, and also metals less preferably used in the integrated circuit such as antimony, gold, silver, and tin. The X is most commonly oxygen (as an unavoidable impurity or as added element), nitrogen, boron, and other elements for adjusting the property.

The content of the M₁ is between 5 at % (here at % represents the atomic percentage) and 98 at %, preferably between 40 at % and 80 at %, and most preferably between 50 at % and 75 at % in some embodiments.

In an embodiment of the present disclosure, the content of germanium in the eutectic memory layer is between 50 at % and 75 at %. In another embodiment of the present disclosure, the content of silicon in the eutectic memory layer is between 15 at % and 75 at %. In still another embodiment of the present disclosure, the content of carbon in the eutectic memory layer is between 5 at % and 20 at %.

The M₂ is one or more element selected from copper, aluminum, tin, antimony, silver, and gold, and the content of the M₂ is between 2 at % and 85 at %.

The X is titanium or at least one element selected from oxygen, carbon, boron and nitrogen. The content of the X is between 0.5 at % and 10 at %. The X can also be an oxide such as silicon dioxide, and the content of such X is between 0.5 at % and 5 at %.

The present disclosure provides a eutectic memory, which comprises a eutectic memory layer. The material of the eutectic memory layer is composed of a binary alloy or a multi-component alloy and compounds thereof, in which a eutectic reaction can occur. The so-called eutectic reaction means that a liquid or a super-cooled liquid (that means an amorphous solid state) generates two or more crystals at the same time during crystallization, which is represented by the following equations:

L←→Crystal 1+Crystal 2+Crystal 3+ . . . (1)

or,

Am←→Crystal 1+Crystal 2+Crystal 3+ . . . (2)

for example,

Amorphous GeAl solid←→Ge crystal+Al crystal (3)

In the Equation (1), the L means melted liquid at a high temperature. The Am in Equation (2) means an amorphous solid phase formed by fast-cooled liquid. The Crystal 1 means the first crystal, the Crystal 2 means the second crystal, and so on.

Through the difference in electrical resistance corresponding to the two different states, namely, the amorphous state and the crystalline states, the eutectic memory layer can represent at least two possible memory digits (a digital 0 and a digital 1).

Specifically, material design of the eutectic memory layer—material of the present disclosure is represented by M₁-M₂-X. The M₁ is a semiconductor element. The M₂ is a metallic element which forms eutectic with the M₁. The X represents an unavoidable impurity or an added element when it is necessary to adjust the property, or both of them. The content of the M₁ is between 5 at % and 98 at %. The material that can be used as the film of the eutectic memory layer must have following characteristics: (1) the material can form an amorphous state after being heated, melted, and quenched; (2) when the amorphous solid is heated above the crystallization temperature, phase-separation occurs so that the material has two or more crystalline phases; (3) the electrical resistance at the amorphous state is at least ten times higher than that of the crystalline states, so as to represent digital signals; (4) under the sub-micron limits, the material has self-assembly capability, so as to enhance electric performance of the memory, and avoid the memory from being failed due to phase-separation.

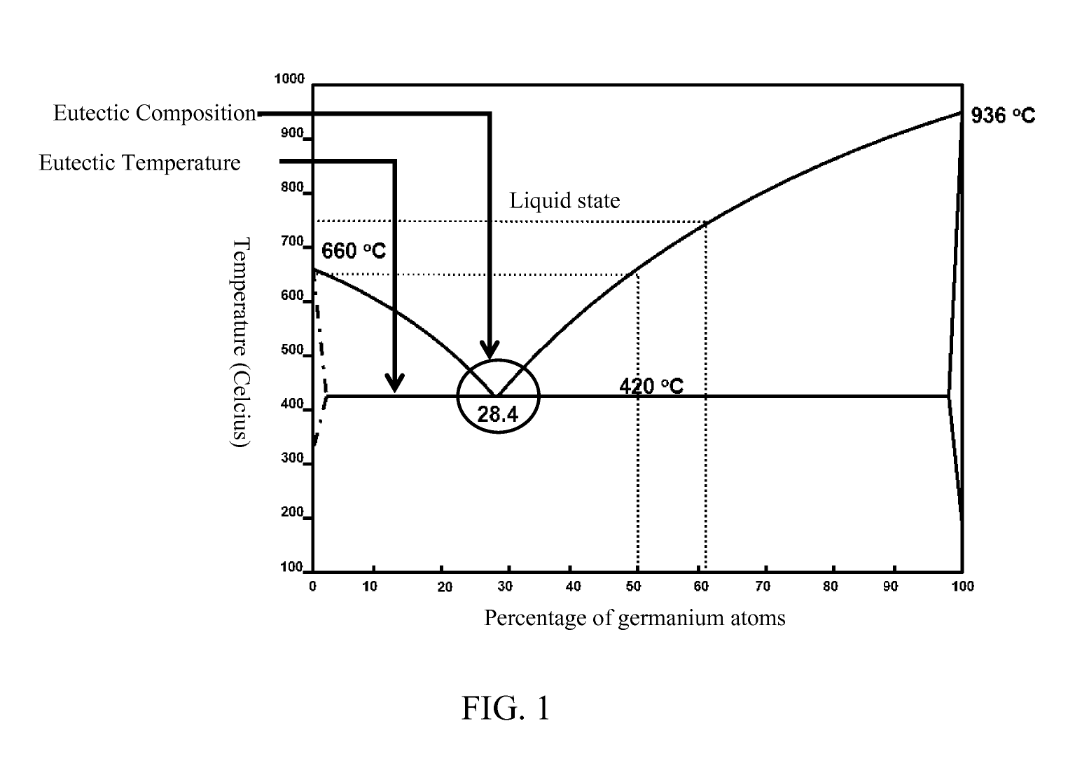

For an example, the M₁ is germanium and the M₂ is aluminum. An equilibrium phase diagram of aluminum-germanium is shown in FIG. 1, which has eutectic features described as follows. The aluminum-germanium has the lowest and constant eutectic temperature (420° C.) and a fixed eutectic composition (28.4 at % Ge), which is noted in FIG. 1. The aluminum-silicon eutectic is similar to the aluminum-germanium, and has a eutectic temperature of 577° C. and a eutectic composition of 12.2 at % Si.

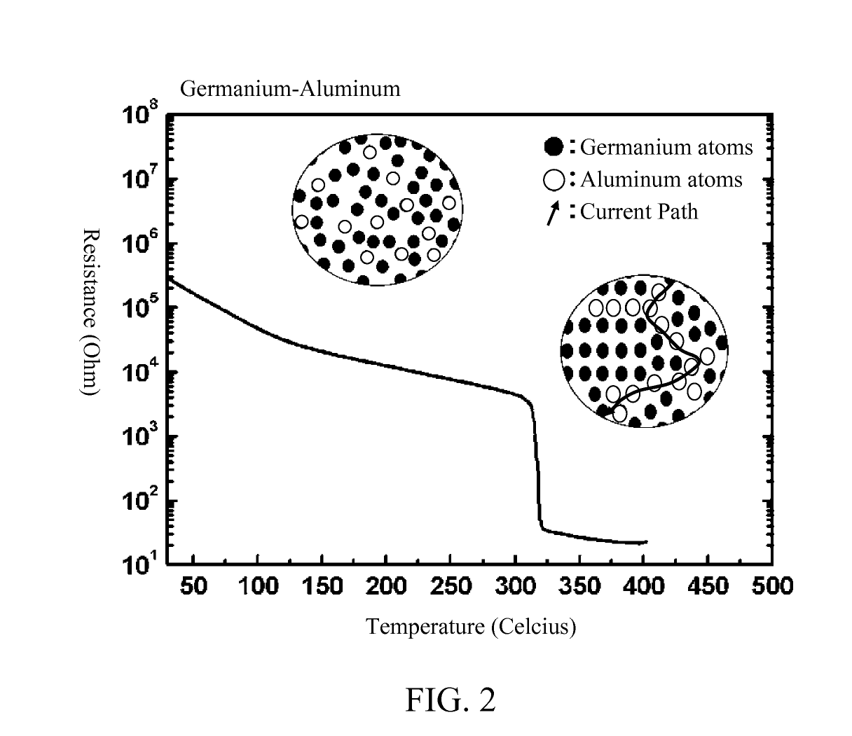

The eutectic memory of the present disclosure also has phase changes, but is totally different from the conventional PRAM. The conventional PRAM is limited in the reversible phase change between the single amorphous phase and the single crystalline phase having the same composition. The reversible phase change of the eutectic memory is between the single amorphous phase and two or more crystalline phases having different compositions. As found in the past researches, in the PRAM, if a second crystal appears, the phase change behavior becomes unstable, thus affecting the long-term stability of the PRAM (for example, during the research of Sb-15 at % Ge phase change alloy, C. Cabral et al. from the IBM company found that germanium crystal is separated out after long time operation of the Sb—Ge alloy having a single phase originally, thus causing deterioration of performance, Applied Physics Letters, 93, 071906, 2008). The present disclosure overcomes the above limitation, and turns the appearance of the two or more crystals advantageous. For example, the eutectic composition has a low melting point. Also, the eutectic means the formation of two separated phases, so that the electric conduction mechanism becomes percolation (as shown in FIG. 2) as being totally different from that of PRAM. In addition, the eutectic composition has a specific atomic composition and a fixed ratio of phase contents. When eutectic reaction takes place in specific hypereutectic or hypoeutectic ranges, the eutectic reaction after the primary crystallization is unique and invariant. Such an effect is similar to self-assembly. This decreases composition sensitivity of the eutectic memory and enhances durability, thus facilitating the industrial application. These are the specific features by which the present disclosure is different from the conventional phase-change memory techniques.

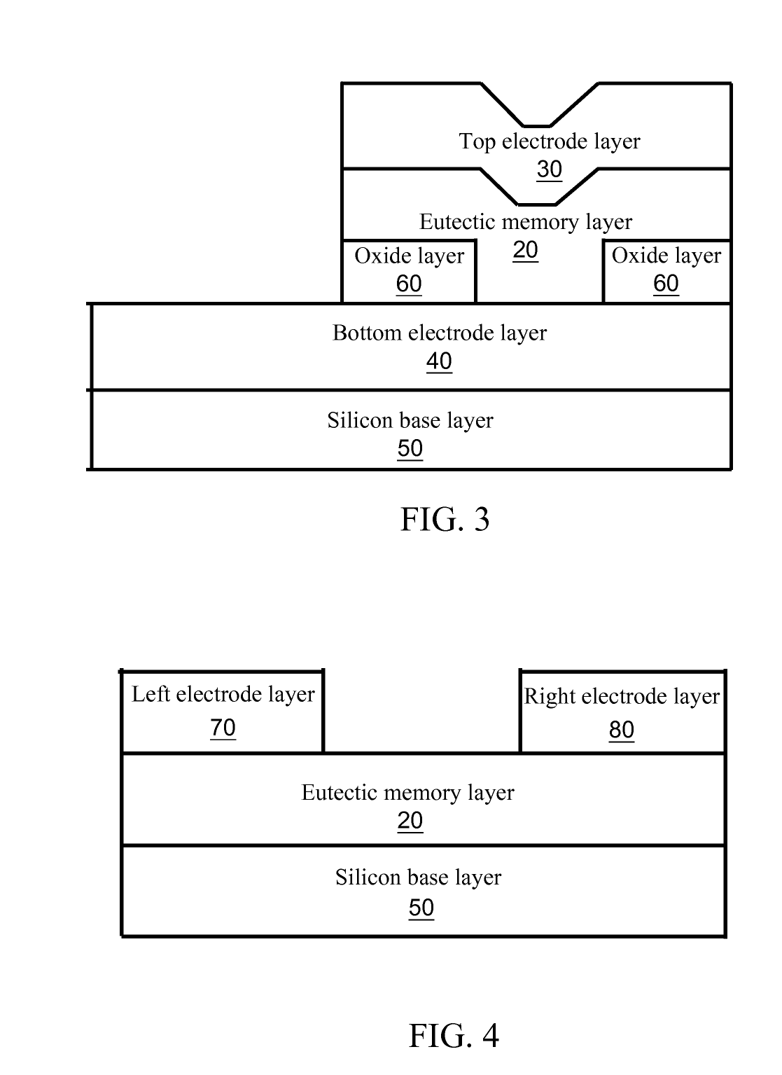

FIG. 3 is a hierarchical structural diagram of a eutectic memory cell. The eutectic memory comprises a eutectic memory layer 20, a top electrode layer 30, a bottom electrode layer 40, a silicon base layer 50, and oxide layers 60. The material of the eutectic memory layer 20 is the same as the above mentioned material (M₁-M₂-X). The eutectic memory layer 20 is located between the top electrode layer 30 and the bottom electrode layer 40. Temperature between the top electrode layer 30 and the bottom electrode layer 40 correlates with current density passing through. The bottom electrode layer 40 is located above the silicon base layer 50. Therefore, a temperature between the bottom electrode layer 40 and the top electrode layer 30 can be changed by controlling magnitude of pulsed current passing through the two electrodes and duration of the current, so as to heat the eutectic memory layer located between the two electrode-layers 40 and 30. The oxide layers 60 are located at two sides of the eutectic memory layer 20 and between the eutectic memory layer 20 and the bottom electrode layer 40. A contacting via exists between the eutectic memory layer 20 and the top electrode layer 30, for providing a better thermal conduction effect for the top electrode layer 30. The silicon base layer 50 can be regarded as a complementary metal oxide semiconductor (CMOS) or a P-N junction diode, and as an access device or selector. The CMOS has a plurality of N poles and P poles. The bottom electrode layer 40 is connected to one of the N poles of the CMOS. A bit decoder (not shown) is also connected to one of the N poles of the CMOS at the same time. A word decoder (not shown) is connected to a P pole. Electrical resistance value of the eutectic memory layer 20 can be determined or changed through control signals of the bit decoder (not shown) and the word decoder (not shown), so as to retrieve or store data of the memory. In an exemplary embodiment, the material of the top electrode layer 30 and bottom electrode layer 40 is chosen from titanium (Ti), titanium tungsten (TiW), titanium nitride (TiN), tungsten nitride (WN), tantalum nitride (TaN), or aluminum titanium nitride (TiAlN).

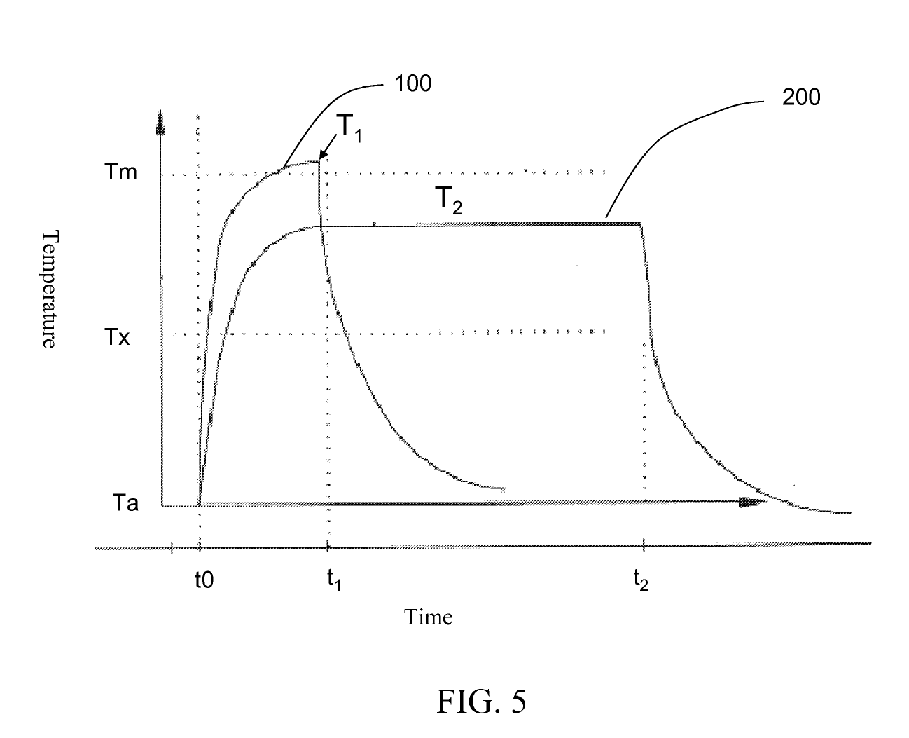

FIG. 4 is a lateral hierarchical structural diagram of a eutectic memory. In order to satisfy wider design requirements, a structure composes of a left electrode layer 70 and a right electrode layer 80 encircling the eutectic memory layer 20 is also available in the eutectic memory. The eutectic memory comprises the eutectic memory layer 20, the left electrode layer 70, and the right electrode layer 80. Temperature between the left electrode layer 70 and the right electrode layer 80 correlates with the current density passing through. Therefore, a temperature between the left electrode layer 70 and the right electrode layer 80 can be changed by controlling magnitude of pulsed current passing through the two electrodes and duration of the current, so as to heat the eutectic memory located between the electrode-layers 70 and 80. In an exemplary embodiment, the material of the left electrode layer 70 and the right electrode layer 80 is chosen form Ti, TiW, TiN, WN, TaN, or TiAlN.

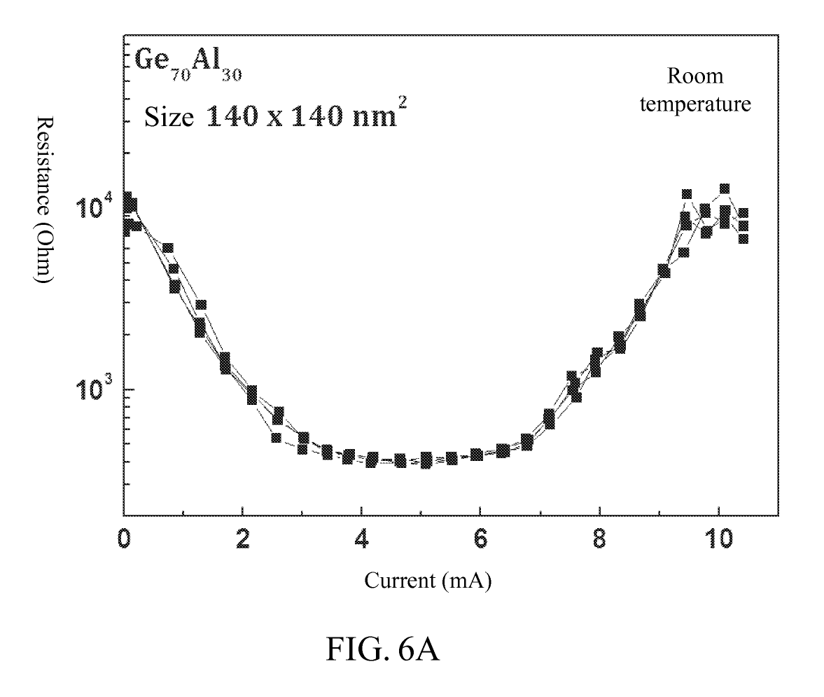

FIG. 5 is a schematic way of controlling temperature changes of the eutectic memory layer according to the present disclosure. A first plot 100 represents that the eutectic memory layer is heated to a temperature T₁ (a first temperature) within a duration from t₀ to t₁. The heating amount is controlled through the magnitude and duration of a pulsed current, and the temperature T₁ is higher than the melting point temperature (Tₘ), so that a state of the eutectic memory is switched to a transient liquid state instantly. The eutectic memory layer is rapidly cooled within a very short period, so that atoms of the material inside the eutectic memory layer are unable to arrange in ordered crystal forms, and thus to be solidified to a super-cooled amorphous state. In such an amorphous state, the atoms arrangement is disordered with a lot of defects (such as free volumes) and is semiconductor when M₁ is Si or/and Ge as the major content. This results in a relatively high first electrical resistance. The second plot 200 represents that the eutectic memory layer is heated to a temperature T₂ (a second temperature) within a duration from t₀ to t₂. The temperature T₂ is higher than the crystallization temperature (Tₓ) of the material but lower than the melting point temperature Tₘ thereof. At this time, a crystallization reaction takes place inside the amorphous eutectic memory layer, and two or more crystalline phases are crystallized at the same time, so that obvious phase-separated phenomenon occurs. If a crystalline phase is a metal phase and the content thereof (which can be adjusted through composition) is sufficient for mutual connectivity, or percolation in other words, after eutectic crystallization, an extremely low resistance state is obtained. For example, the eutectic memory having a material of germanium-aluminum alloy, during eutectic crystallization state, an amorphous state of the eutectic memory is separated into two independent crystalline phases of germanium and aluminum. Germanium phase having practically no solid solubility of Al in it is a semiconductor with very high electrical resistance. The aluminum having practically no solid solubility of Ge in it is a good conductor possessing a low resistance. Therefore, in the phase-separated state, if the content of the aluminum phase is sufficient to form conducting paths for electric conduction, the eutectic memory has a relatively low resistance. If the composition is Ge—Al—Sn, the amorphous Ge—Al—Sn is crystallized into three crystalline phases of Ge, Al, and Sn; the three phases are pure without mutual solid solubility at low temperatures. In other examples, the amorphous state of the silicon-gold alloy is crystallized into two phases of silicon and gold; while the amorphous state of the carbon-antimony alloy is crystallized into two phases of carbon and antimony.

In the embodiments of the present disclosure, the material of the eutectic memory layer is deposited through vacuum sputtering. Direct current (DC) or radio frequency (RF) sputtering is selected depending on whether the target material is a good electric conductor or not. The target material can be an alloy target (for example, Ge₇₀Al₃₀) or pure element targets (for example: a germanium target, an aluminum target, a silicon target, a copper target . . . etc). A schematic structure of a test cell of the eutectic memory is shown in FIG. 3, fabrication of which uses 0.18-micron standard back-end-of-line process. An eight-inch wafer is used, and a silicon dioxide passivation layer is grown thereon. A bottom electrode (for example, TiN/Ti) and an oxide layer (SiOx) are deposited through a physical vapor deposition (PVD) process. Subsequently, a via and a bottom electrode contact layer are defined through a photolithographic process. Next, a layer of photoresist is covered. A second defined pattern is then formed through the photolithographic process, which covers the via of the bottom electrode. Then a top electrode contact layer is defined on the oxide layer. The above processes are all performed in a clean room. Later, the wafer is taken out to another laboratory, sputtered with a eutectic memory material, and then deposited with a top electrode, and finally excessive photoresist is removed with acetone or a stripper through a lift-off method, so that the test cell is separated. The experimental measurements comprise: measurement of film electrical property through a four-point probe method, especially a resistance-temperature plot in a heating up process; measurement of thermal property of powders stripped from films using a differential thermal analysis method; and measurement of electrical properties of the eutectic memory test-cells such as a resistance-current (R-I) plot or a resistance-voltage (R-V) plot with a pulse-generator and a high frequency oscillograph.

According to the first embodiment of the present disclosure, the material of the eutectic memory layer comprises: M₁, which is the semiconductor element germanium and M₂, which is metallic element aluminum; and X, which is oxygen, an unavoidable impurity element unable to be completely avoided in the manufacturing process (usually less than 2 at %, in all the embodiments below). The content of M₁ is preferably between 5 at % and 98 at %, more preferably between 40 at % and 80 at %, and most preferably between 50 at % and 75 at %.

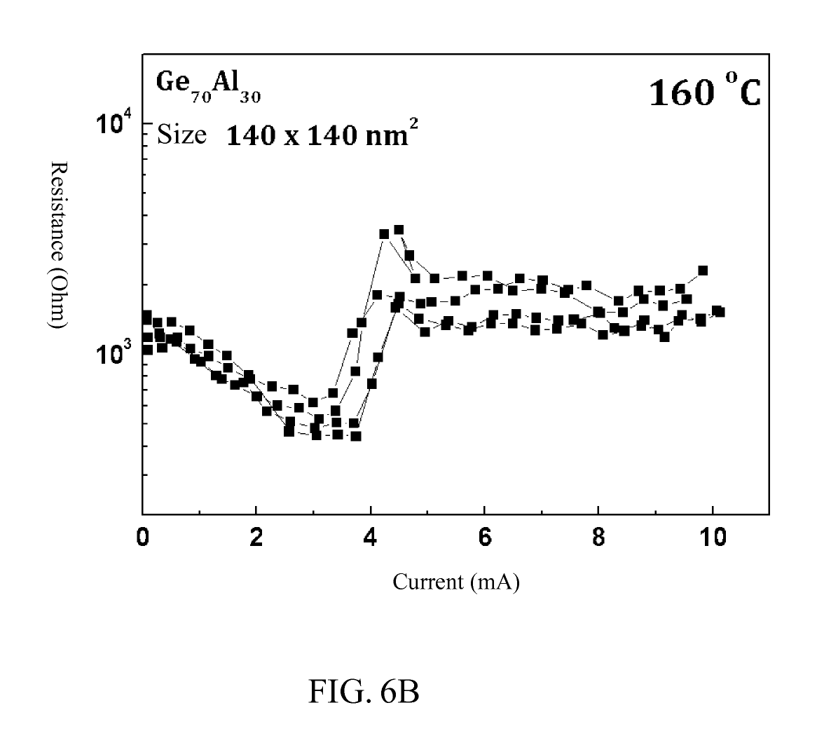

FIGS. 6A and 6B are diagrams of current-resistance relation from test-cells of the eutectic memory according to the first embodiment of the present disclosure, which represents operation performance at room temperature (6A) and at a high temperature (6B) respectively. In FIGS. 6A and 6B, connecting lines of data points represent experimental results for different testing runs. The operation of the memory cell is controlled through a pulsed current. The pulsed current in FIGS. 6A and 6B is set with pulse-widths (pulse duration) which can be adjusted between 500 nanoseconds (ns) and 20 ns. If the pulse duration is not specifically given, the pulse duration is 500 ns.

The operation temperature in FIG. 6A is at room temperature. As can be seen from FIG. 6A, in the process when the pulsed current amplitude passing through the top and the bottom electrode layers gradually increases from 0 mA to 3 mA, the electrical resistance of the eutectic memory cell is gradually decreased from the high resistance state, representing that eutectic crystallization takes place gradually with increasing current amplitude. When the current is increased to 3 mA, the resistance reaches the lowest state (the eutectic crystallization is finished). This action is referred to as SET or WRITE. When the pulsed current gradually increases from 3 mA to 7 mA, the resistance of the eutectic memory cell keeps unchanged at the lowest value, representing a state that the eutectic-crystallized phases are stable. When the pulsed current is gradually increased from 7 mA to 9.5 mA, the resistance gradually increases from the low resistance state to high resistance state, representing that the eutectic crystals gradually becomes amorphous and the high resistance state is eventually recovered after 9.5 mA. This process is referred to as RESET or ERASE. When the current is higher than 9.5 mA, the eutectic memory cell keeps at a high resistance state.

FIG. 6A also shows that in both situations of setting down from the high resistance state and resetting up form the low resistance state, the test-cells has a resistance difference higher than 33 times. Also, the electrical resistance of the test-cell assumes gradual drop or gradual rise characteristics with the amplitude of pulsed current. Therefore, the test-cells can be set or reset to a plurality of resistance states by using a control circuit, that is, the test cell has a multi-level memory capability.

The operation temperature in FIG. 6B is at 160° C. isothermally. As can be seen from FIG. 6B, when the pulsed current is 2.5 mA, the eutectic memory cell can be set to a low resistance state. When the pulse current is increased to 4.5 mA, the memory cell is reset back to a high resistance state. Two characteristics of the eutectic memory cell are also shown here: (1) the test cell can be operated at a high temperature (in this example, 160° C.); and (2) the high temperature environment decreases the necessary operation current accordingly. The two characteristics are not seen in phase-change memories in any other literature.

The following table shows composition effect on performance of eutectic memory materials according to a second embodiment of the present disclosure. In this embodiment, germanium aluminum alloys are taken as examples. As can be seen from the table, when the content of germanium is changed from 69 at % to 52 at %, and the content of aluminum is between 31 at % to 48 at %, a eutectic point (that is, the melting point) is between 420° C. and 425° C., practically the same considering the accuracy of temperature measurements.

| | Electrical | Electrical | | | |
|---|---|---|---|---|---|
| | resistivity at | resistivity at | | Crystallization | Melting |
| Ge—Al | amorphous | crystallized | Resistivity | temperature | point |
| composition | state (Ω-cm) | state (Ω-cm) | ratio | (° C.) | (° C.) |
| Ge₅₂Al₄₈ | 2.16 | 8.81 × 10⁻⁴ | 2450 | 296 | 420 |
| Ge₅₄Al₄₆ | 3.02 | 2.38 × 10⁻⁴ | 12690 | 296 | 424 |
| Ge₆₁Al₃₉ | 4.83 | 5.37 × 10⁻⁴ | 8990 | 314 | 424 |
| Ge₆₉Al₃₁ | 6.09 | 1.74 × 10⁻⁴ | 35000 | 338 | 425 |

In consideration of experimental errors, the eutectic point can be regarded as unchanged, which conforms to the eutectic temperature 420° C. as shown in the phase diagram, FIG. 1. As can be seen, even the material compositions are different the melting points are the same. This feature enables the memory cell with stable operation characteristics, since the melting temperature keeps at the same value when the composition is manifestly changed. The table also shows that the crystallization temperature increases with the increase of germanium content, from 296° C. (Ge is between 52 at %˜54 at %) to 338° C. (Ge is 69 at %). In addition, it can be observed from the table that the resistance value in the amorphous state is at least more than two thousand times higher than the resistance value in the phase-separated crystalline state. However, in other examples such as in a Ge—Cu alloy system (Cu is between 2 at % and 8 at %), the difference in electric resistance values is about more than ten times.

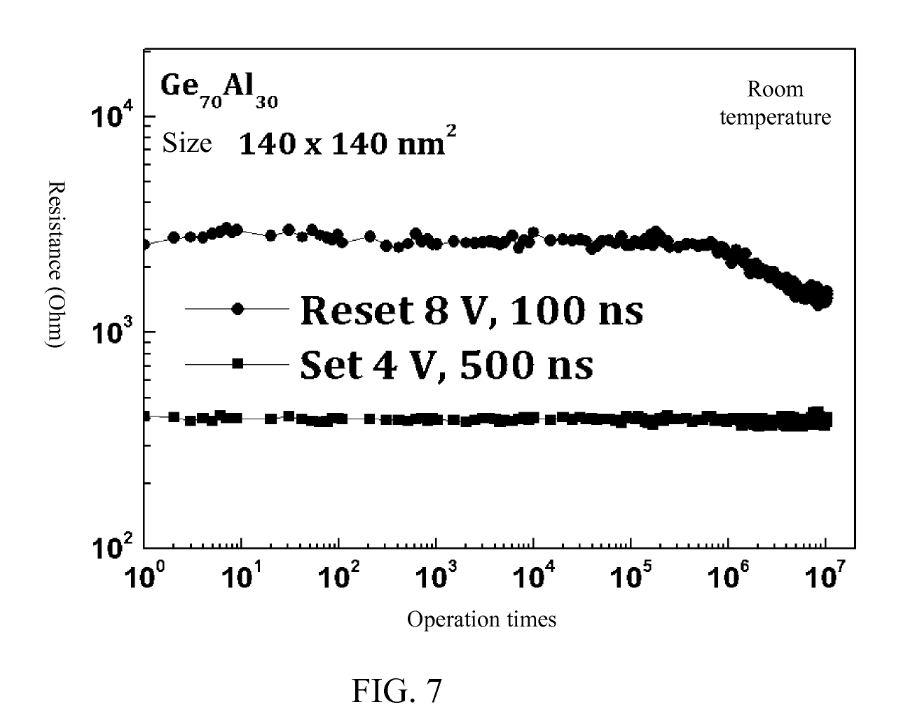

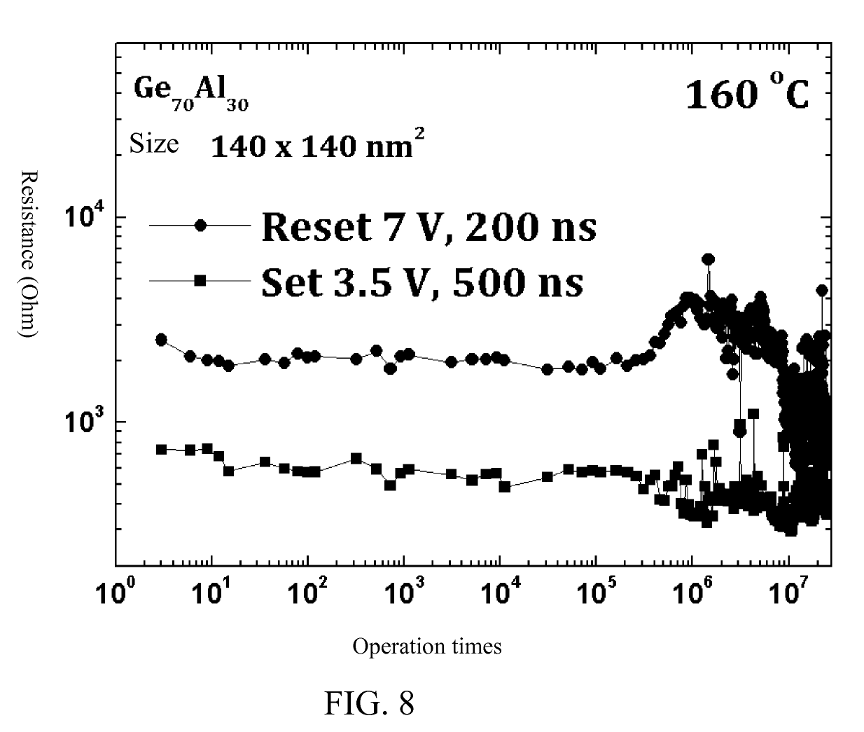

FIGS. 7 (at room temperature) and 8 (at high temperature, 160° C.) are experimental data of operation cycles according to the third embodiment. This experimental operation is done for resetting a first memory state (the ‘Reset’ labeled in FIGS. 7 and 8) to a voltage of 8V with a pulse-width of 100 ns, and setting to a second memory state (the ‘Set’ labeled in FIGS. 7 and 8) to a voltage of 4V and a pulse-width of 500 ns. As can be observed in FIG. 7, during the operation at room temperature, after repetitive changes of the memory states for one million times, the eutectic memory layer can still maintain stable two-level resistance characteristics. Even after repetitive operations for ten million times (the experiment is terminated instead of test-cell failure), the two-levels resistance characteristics of the eutectic memory is still distinguishable. As can be observed in FIG. 8, in the operation at 160° C., even if the eutectic memory layer is in an environment at so high a temperature, the memory-cell still survives after repetitively set-reset for at least three million times with distinguishable two-level resistance characteristics.

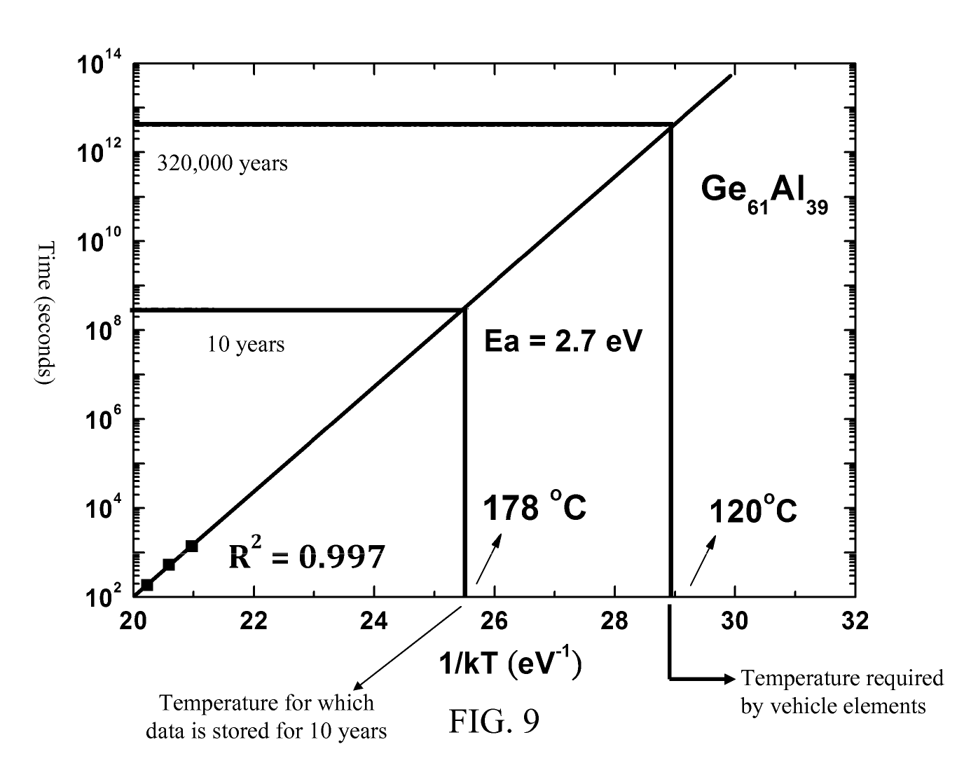

FIG. 9 is a diagram according to the fourth embodiment of the present disclosure, in which the Y-axis is time at logarithmic scale and the X-axis is reciprocals of temperature in degree Kelvin. The time-to-failure is defined when the electrical resistance of amorphous films is decreased to a half of its original value when keeping at a constant high temperature. As shown in FIG. 9 is the plot of the time-to-failure of Ge₆₉Al₃₁ amorphous films versus reciprocals of the constant keeping temperatures. A straight line is attained conforming to an Arrhenius relation of a thermal activation reaction. Therefore the time-to-failure of Ge₆₁Al₃₉ amorphous films can be extrapolated beyond the tested temperatures. FIG. 9 shows that for a eutectic memory fabricated with the composition according to the present embodiment, memory data can be kept for ten years at a constant temperature 178° C., and the data can be kept for 320,000 years at a temperature 120° C. (a normal working temperature extended for automobile electronics). That is to say, data in eutectic memory is not damaged permanently when storing at 120° C.

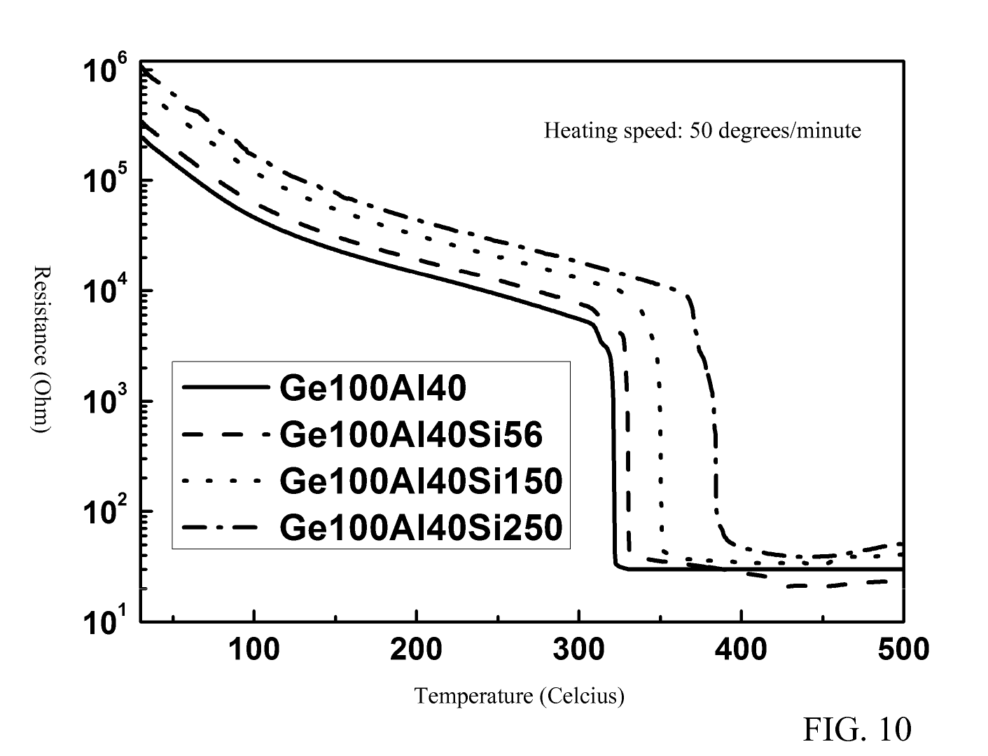

FIG. 10 shows changes of electrical resistance in a heating process when silicon is added in a germanium-aluminum film (X includes Si and unavoidable oxygen impurity) according to a fifth embodiment of the present disclosure. According to FIG. 10, the crystallization temperature increases with increasing Si content (the sputtering power of Si target increases). The crystallization temperature slowly increases from 314° C. without any Si addition to 325° C. (when the sputtering power of the silicon target is 56 W), 340° C. (when the sputtering power of the silicon target is 150 W), and 368° C. (when the sputtering power of the silicon target is 250 W). The electrical resistance after crystallization also manifestly increases. It shows that silicon is very effective as an adjustment element. One who skills in this art can further modify Si content to optimize crystallization temperature and other properties.

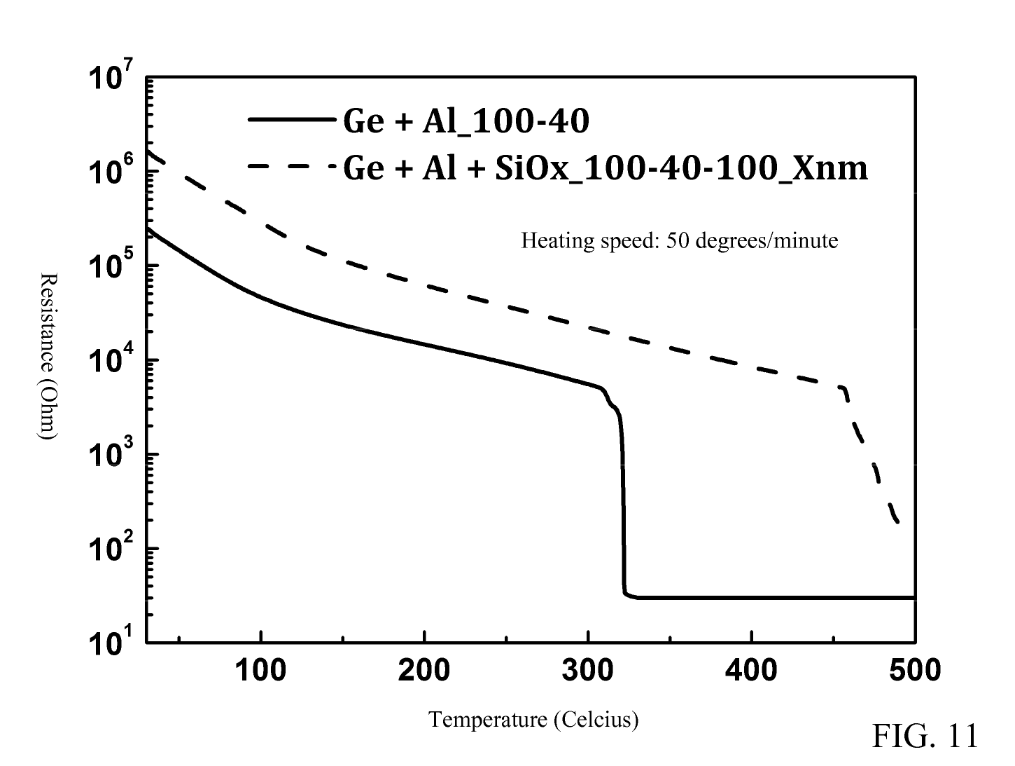

FIG. 11 shows changes of electrical resistance in a heating process when silicon dioxide is added into a germanium-aluminum film (X is SiO₂ and unavoidable oxygen impurities) according to a sixth embodiment of the present disclosure. According to FIG. 11, the crystallization temperature increases with increasing content of the silicon dioxide (the sputtering power of SiO₂ target increases). The crystallization temperature rises from 314° C. without any addition rapidly to 456° C. (when the sputtering power of the silicon dioxide target is 100 W). The electrical resistance after crystallization also increases accordingly. It shows that the silicon dioxide is also very effective as an adjustment additive. One who skills in this art can further reduce the quantity of silicon dioxide to optimize crystallization temperature and other properties.

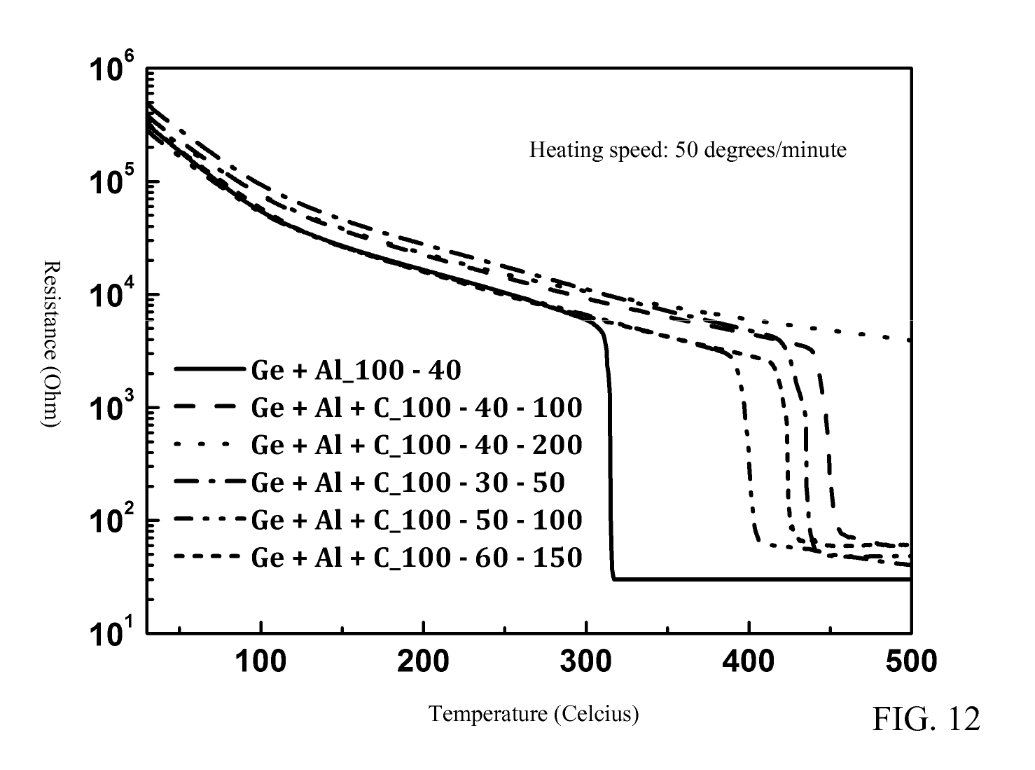

FIG. 12 shows changes of electrical resistance in a heating process when carbon is added in a germanium-aluminum film (X is C and unavoidable oxygen impurity) according to a seventh embodiment of the present disclosure. According to FIG. 12, the crystallization temperature changes obviously with different contents of the germanium, aluminum, and carbon (sputtering power of each target changes respectively). The crystallization temperature is changed between 314° C. (without any addition) and 440° C. When the content of the carbon is too high (the sputtering power of the carbon reaches the highest power 200 W), the crystallization temperature is higher than 500° C. beyond our testing limit. The film composition is Ge₄₈Al_{46.6}C_{5.4} when the sputtering powers of the Ge, Al, and C targets are respectively 100 W, 60 W, and 150 W through composition analysis. The amorphous Ge₄₈Al_{46.6}C_{5.4} film has a crystallization temperature 423° C., and possesses a high electrical resistance up to 5280 times higher than the low resistance state thereof. The electrical resistance of crystallized films also increases with increasing carbon content. In this embodiment, it shows that carbon is very effective as an adjustment element. One who skills in this art can further modify the quantity of added carbon to optimize crystallization temperature and other properties.

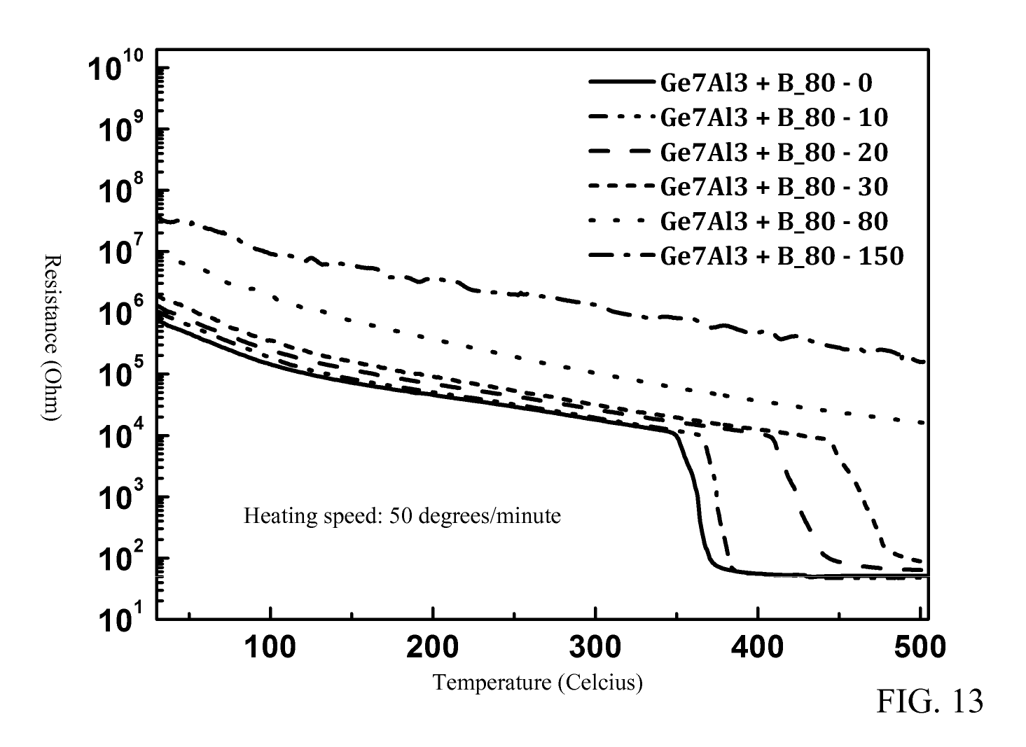

FIG. 13 shows changes of resistance in a heating process when boron is added in a germanium-aluminum film (X is B and unavoidable oxygen impurities) according to an eighth embodiment of the present disclosure. According to FIG. 13, the crystallization temperature changes obviously with different contents of the germanium, aluminum, and boron (changes in sputtering power of the germanium-aluminum alloy-target and a boron target). The crystallization temperature increases from 352° C. without any addition to 450° C. with increasing boron content (even higher than 500° C. when the content of the boron is too high), and a ratio between the high electrical resistance and the low electrical resistance is greater than 10000. After crystallization, the electrical resistance of boron-added film also increases with boron content. In this embodiment, it shows that the boron is very effective as an adjustment element. One who skills in this art can further modify boron content to optimize crystallization temperature and other properties.

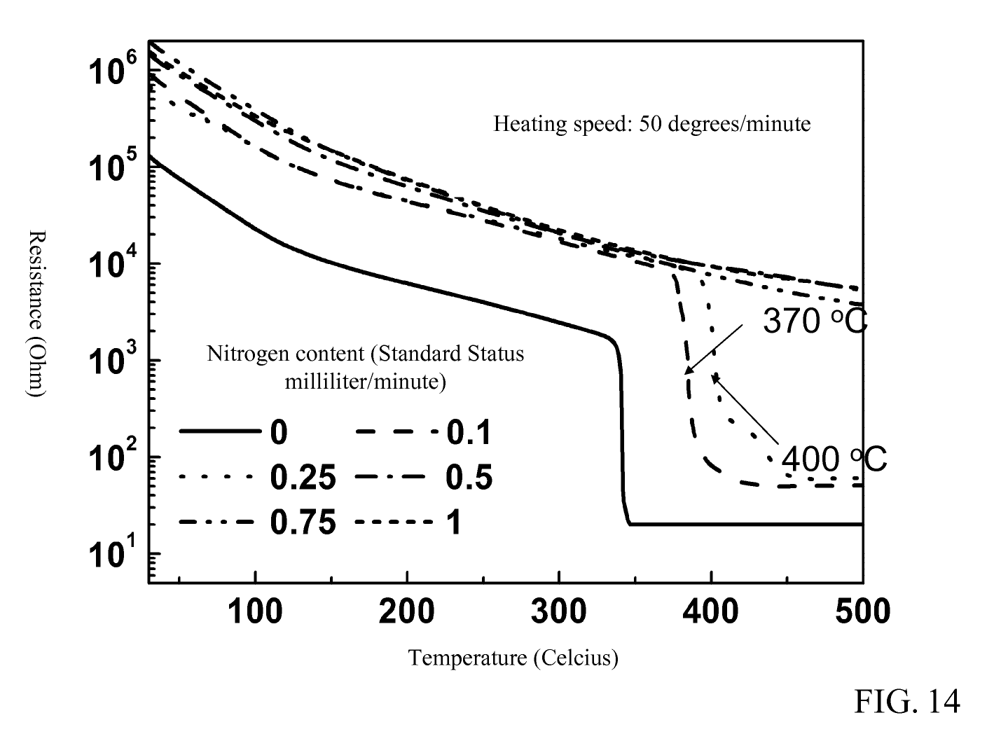

FIG. 14 shows changes of electrical resistance in a heating process when nitrogen is added in a germanium-aluminum film (X is N and unavoidable oxygen impurities) according to a ninth embodiment of the present disclosure. According to FIG. 14, the crystallization temperature obviously rises with the increase of nitrogen flow rate during the sputtering. With the increase of nitrogen content, the crystallization temperature rises from 348° C. without any addition to 370° C., 400° C., and then higher than 500° C. respectively. After crystallization, the resistance of each film also greatly rises with the increase of nitrogen content. In this embodiment, it shows that nitrogen is very effective as an adjustment element. One who skills in this art can further modify nitrogen content to optimize crystallization temperature and other properties.

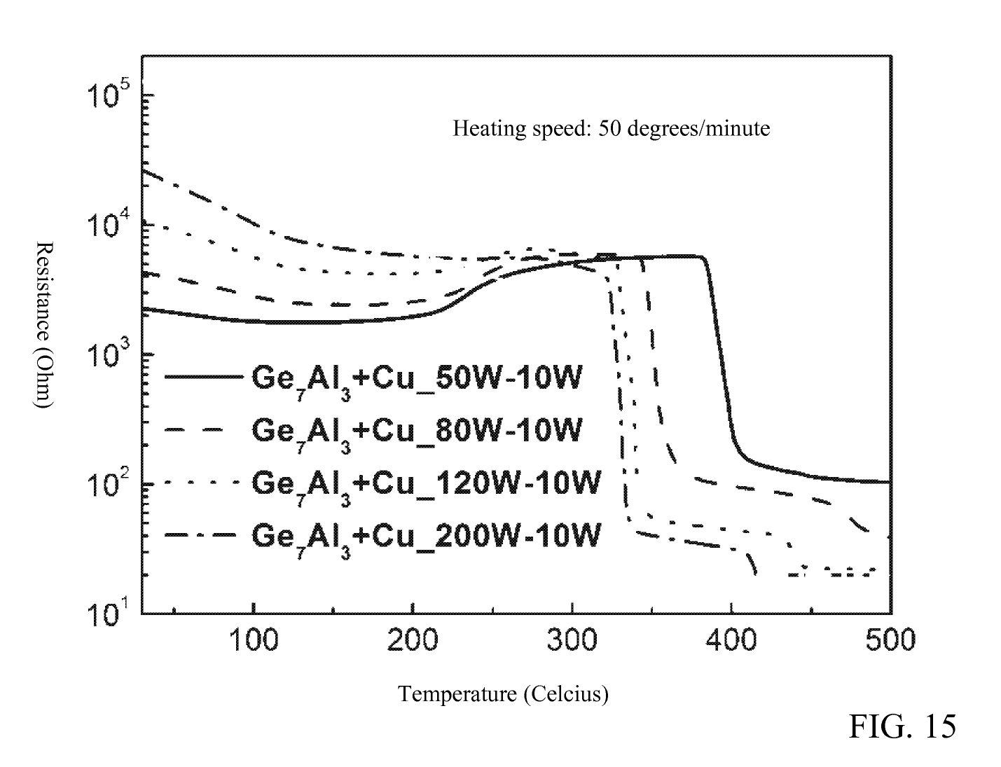

FIG. 15 shows the change of electrical resistance in a heating process when copper is added in a germanium-aluminum film (X is Cu and unavoidable oxygen impurities) according to a tenth embodiment of the present disclosure. According to FIG. 15, the crystallization temperature changes obviously with changes in sputtering power of the germanium-aluminum alloy-target and a copper target. The crystallization temperature drops slightly with the small amount of copper addition from 348° C. (without any addition) and then increases; and also a two-stage crystallization phenomenon occurs. Most specifically in the heating process, the copper-added amorphous film shows a intermittent rise in electrical resistivity at an intermediate temperature range before crystallization; and then the electrical resistance drops rapidly when the crystallization occurs. After complete crystallization, the electrical resistance of copper added films increases obviously versus that of un-added film. After analysis, the content of the copper is not higher than 9 at % in the present embodiment. One who skills in this art can further modify copper content to optimize crystallization temperature and other properties.

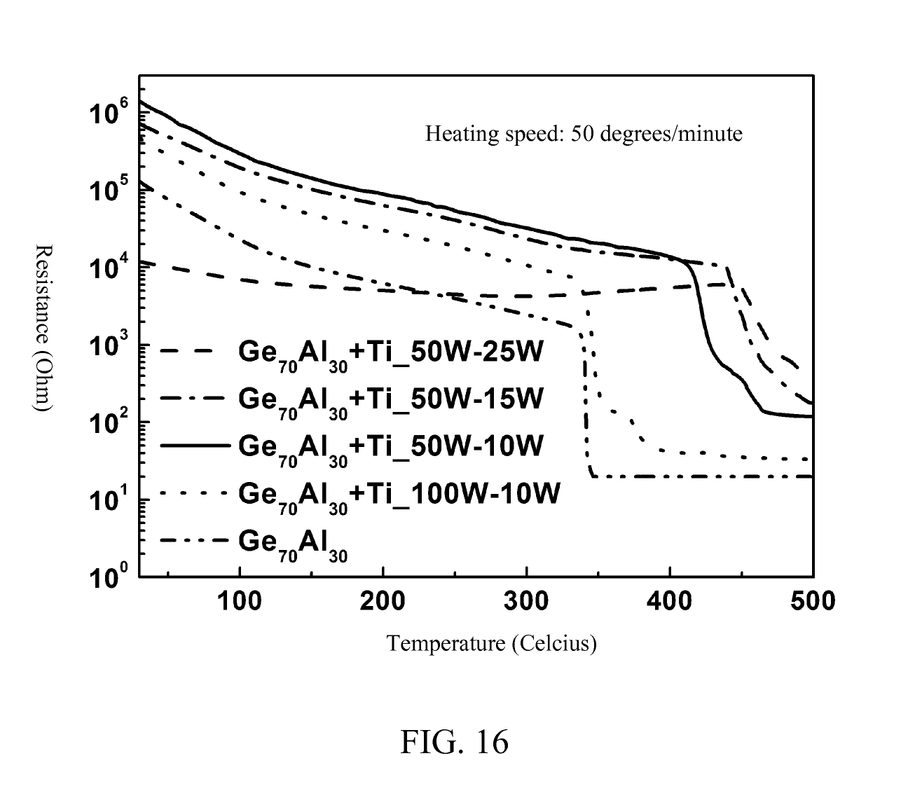

FIG. 16 is an electrical resistance versus temperature diagram of an amorphous film obtained by adding titanium into Ge₇₀Al₃₀ according to an eleventh embodiment of the present disclosure. According to FIG. 16, the crystallization temperature changes obviously with the changes of a power ratio (RW) between the sputtering power of the germanium-aluminum alloy-target and the sputtering power of the titanium target. When the RW is 1:0.1, 1:0.2, 1:0.3, and 1:0.5, respectively, the crystallization temperature is 348° C. (the same as that when nothing is added), 415° C., 440° C., and 450° C., respectively. And the electrical resistance in the crystalline state also increases with added Ti obviously. In this embodiment, it shows that the titanium is a very effective adjustment element. One who skills in this art can further modify titanium content to optimize crystallization temperature and other properties.

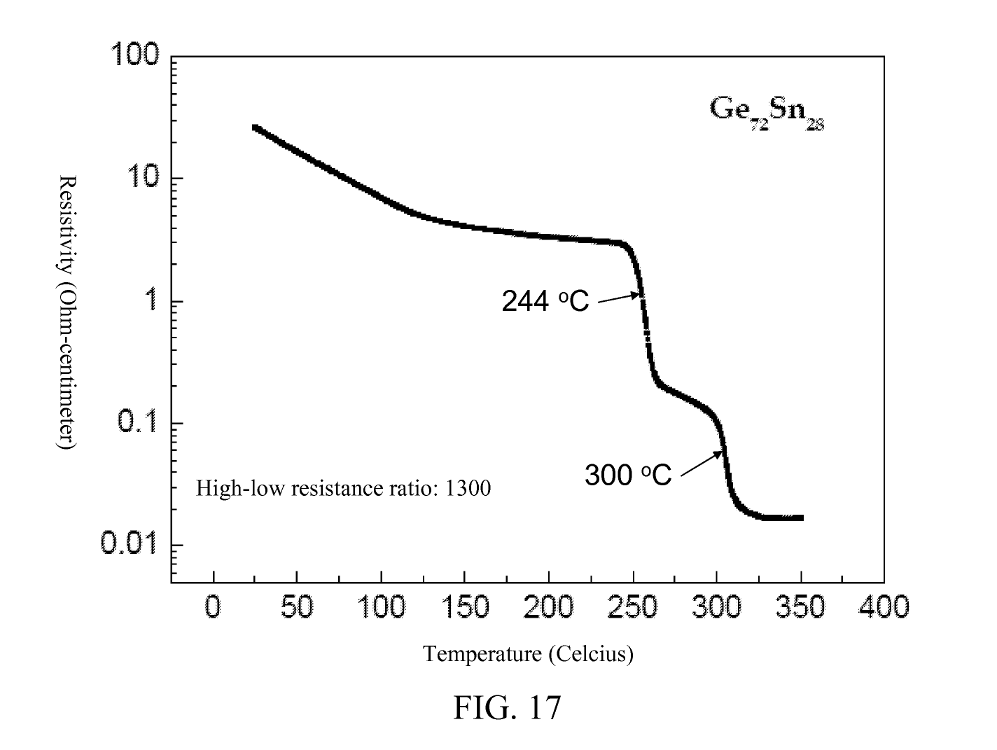

FIG. 17 is an electrical resistance versus temperature diagram of an amorphous film as a eutectic memory layer composes M₁ the semiconductor element germanium and M₂ the metallic element tin according to a twelfth embodiment of the present disclosure. As can be seen from FIG. 17, two-stage crystallization is achieved and the crystallization temperatures are 244° C. and 300° C., respectively. A ratio of electrical resistances between the amorphous state and the crystalline state reaches 1300. Therefore, Ge—Sn is also a suitable eutectic phase-change material system. Tin can also be used as a modifying element X added for performance adjustments.

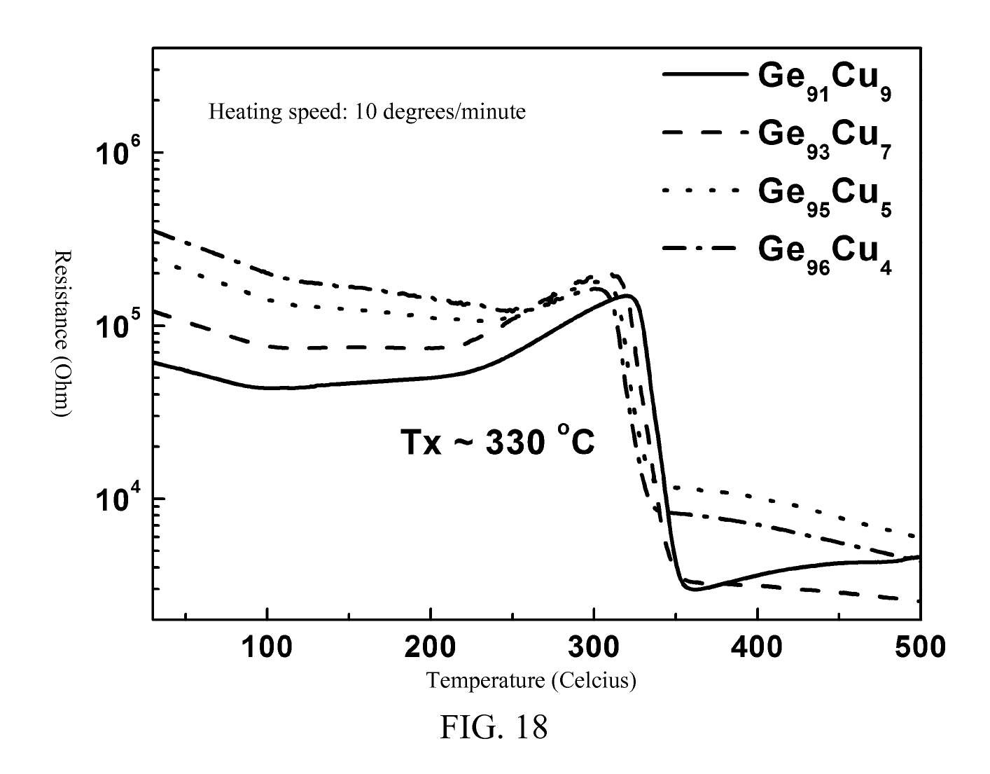

FIG. 18 is an electrical resistance versus temperature diagram of an amorphous film as a eutectic memory layer composes M₁ the semiconductor element germanium and M₂ the metallic element copper according to a thirteenth embodiment of the present disclosure. As can be seen from FIG. 18, electrical resistance drops due to eutectic crystallization. Specifically, the crystallization temperature does not vary much due to different copper contents, but remains between 310° C. and 325° C. It is difficult to add copper into germanium as the sputtering power in the sputtering process is not high. As for each plot in FIG. 18, the copper content is in a range between 2 at % and 9 at %. That is to say, germanium content can be up to 98 at %. The ratio between electrical resistances of the amorphous state and that of crystalline state is also more than 10. An example that copper is used as X, an element added for performance adjustment, is already disclosed in the tenth embodiment.

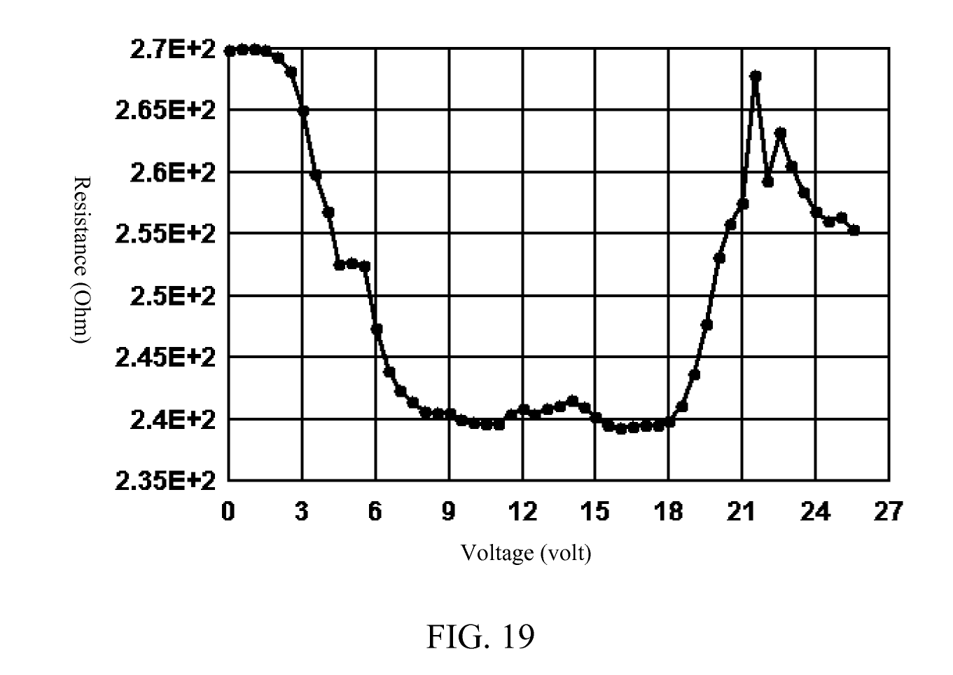

FIG. 19 is an electrical resistance versus voltage diagram of a test-cell made of germanium-copper (Ge₉₆Cu₄) under a pulsed voltage with 10 ns pulse-width according to a fourteenth embodiment of the present disclosure. FIG. 19 shows that the Ge₉₆Cu₄ can be set-reset under a very high speed, 10 ns. The resistance ratio is sufficient to distinguish two electrical resistance levels.

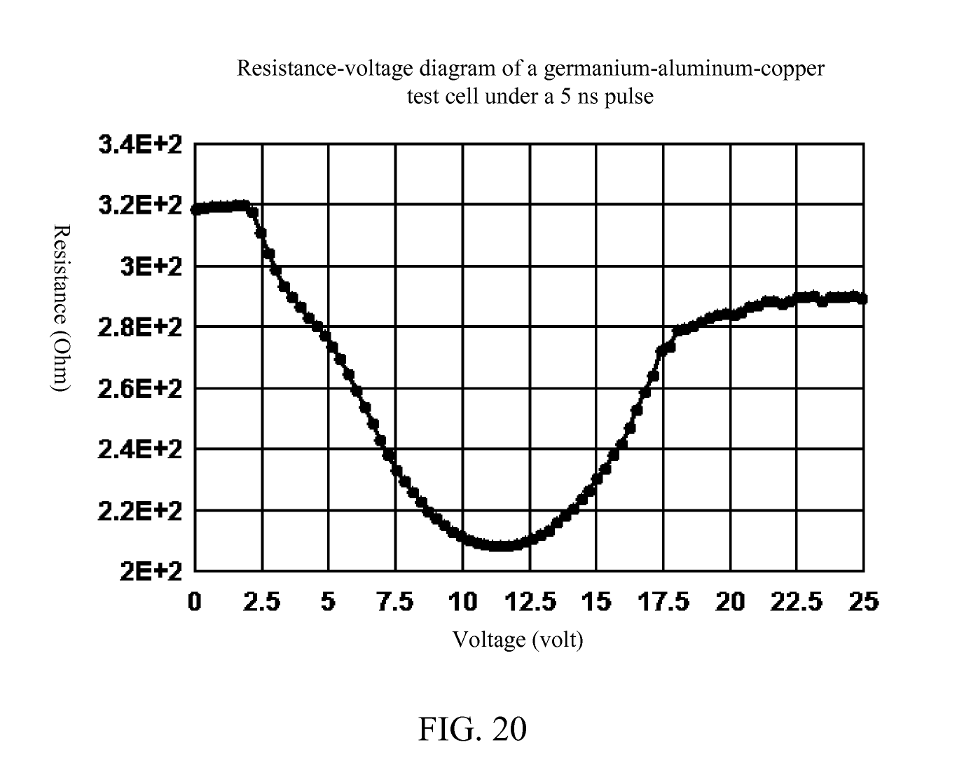

FIG. 20 is a electrical resistance versus voltage diagram of a Ge—Al—Cu test-cell under a pulsed voltage with 5 ns pulse-width according to a fifteenth embodiment of the present disclosure. As shown in FIG. 20, the Ge—Al—Cu test-cell can be set-reset under a very high speed, 5 ns. The resistance ratio is sufficient to distinguish two electrical resistance levels.

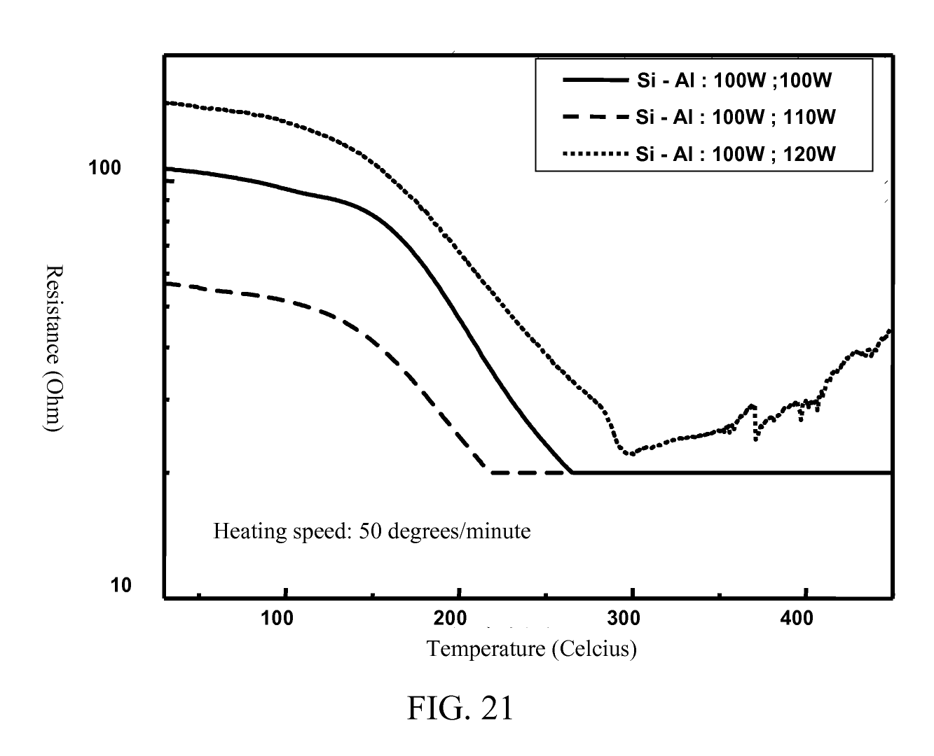

FIG. 21 is an electrical resistance versus temperature diagram of an amorphous film as a eutectic memory layer composes M₁ the semiconductor element silicon and M₂ the metallic element aluminum according to a sixteenth embodiment of the present disclosure. As can be seen from FIG. 21, electrical resistance drops precipitously due to eutectic crystallization. Specifically, the electrical resistance after crystallization reaches the lower limit of the experimental instruments. The crystallization temperature is about 160° C. The electrical resistance ratio between the amorphous state and the crystalline state is higher than 10 for a group of compositions. In addition, it is also discovered in the present disclosure that the most preferable silicon content of Si—Al is between 15 at % and 75 at %.

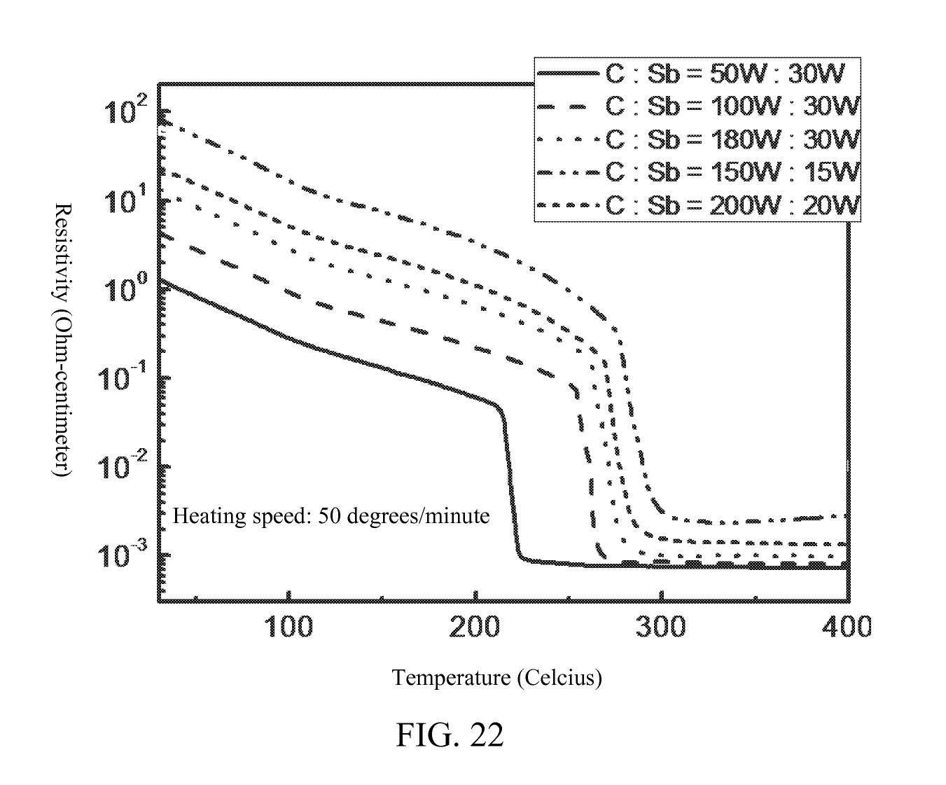

FIG. 22 is an electrical resistance versus temperature diagram of an amorphous film to be used as a eutectic memory layer composes M₁ the element carbon and M₂ the metallic element antimony according to a seventeenth embodiment of the present disclosure. As can be seen from FIG. 22, electrical resistance abruptly drops due to eutectic crystallization. The crystallization temperature is higher than 200° C. The electrical resistance ratio between the amorphous phase and crystalline phase is higher than 1000. In addition, in this embodiment, it is also found that most preferable content of carbon is between 2 at % and 20 at %. Taking the composition C₁₇Sb₈₃ as an example, the crystallization temperature is 280° C. and the melting point is 622° C. The electrical resistance ratio between the amorphous state and the crystalline state is 60000.

Compared with the prior arts, embodiments of the present disclosure disclose various novel and advanced features. (1) The eutectic memory materials have a wide processing window, simplified fabrication, low cost, and no pollution. (2) Materials that are totally compatible with the front-end-of-line process of the integrated circuit can be selected. (3) As the eutectic temperature represents low co-melting temperature in materials science, the melting point can be effectively lowered, so as to eliminate the defect arisen from high melting point of conventional chalcogenides. (4) The crystallization temperature is high, the eutectic point is low, and the thermal stability is much enhanced. (5) Through addition of a third element, the crystallization temperature and the electrical properties after crystallization can be easily adjusted at will. (6) By virtue of eutectic reaction, the materials change structures conforming to a specific phase ratio with a wide tolerable composition range. That is to say, the eutectic materials selected for the present disclosure are characteristic of self-assembly like structure evolution thus enable higher operation stability. (7) For the eutectic memory disclosed in present disclosure, some compositions show high temperature operability, and it has been already verified that the normal operation temperature reaches no less than 160° C. (8) The disclosed eutectic memory materials are nonpoisonous, thus are characteristic of being green and environment friendly. (9) As the eutectic memory materials can directly accommodate the front-end-of-line processing of the integrated circuit, more options and applicability is greatly enhanced in the application designs.

Persons skilled in the art can easily find many eutectic alloy systems, for example, Ge—Ag, Ge—Au, Si—Au, Si—Cu, Si—Ag, Mg—Sb, and Ga—Sb, or other eutectic alloy material systems from the alloy phase diagrams or even ternary alloys as inspired under the teaching of the principles and embodiments disclosed in the present disclosure. Any material systems having the characteristics disclosed in the above paragraph should fall within the protection scope of the present disclosure.

What is claimed is:

1. A eutectic memory, comprising a eutectic memory layer, wherein material of the eutectic memory layer is formed of elements M₁-M₂-X, the M₁-M₂ is a eutectic alloy system, the M₁ is at least one element selected from the group consisting of germanium, silicon, and carbon, the M₂ is a metallic element, and the X is an impurity or an added element.

2. The eutectic memory according to claim 1, wherein content of the M₁ is between 5 at % (atomic percentage) and 98 at %.

3. The eutectic memory according to claim 1, wherein content of the M₁ is between 40 at % and 80 at %.

4. The eutectic memory according to claim 1, wherein content of the M₁ is between 50 at % and 75 at %.

5. The eutectic memory according to claim 1, wherein the M₂ is one or more elements selected from copper, aluminum, tin, antimony, silver, and gold; and content of the M₂ is between 2 at % and 85 at %.

6. The eutectic memory according to claim 1, wherein the X is at least one or more elements selected from oxygen, carbon, boron, and nitrogen; and content of the X is between 0.5 at % and 10 at %.

7. The eutectic memory according to claim 1, wherein the X is titanium and content of the X is between 0.5 at % and 10 at %.

8. The eutectic memory according to claim 1, wherein the X is silicon dioxide and content of the X is between 0.5 at % and 5 at %.

9. The eutectic memory according to claim 1, wherein the eutectic memory further comprises a pair of electrode layers, and the eutectic memory layer is located between the pair of electrode layers.

10. The eutectic memory according to claim 9, wherein the temperature of the eutectic memory layer in between the pair of electrode layers is positively correlated with the current density passing through.

11. The eutectic memory according to claim 9, wherein material of electrode is selected from the group consisting of titanium (Ti), titanium tungsten (TiW), titanium nitride (TiN), tungsten nitride (WN), tantalum nitride (TaN), and aluminum titanium nitride (TiAlN).

12. The eutectic memory according to claim 9, wherein the pair of electrode layers comprises a top electrode layer and a bottom electrode layer.

13. The eutectic memory according to claim 9, wherein the pair of electrode layers comprises a left electrode layer and a right electrode layer.

14. A eutectic memory, comprising:
a eutectic memory layer, is heated via a pulsed current of proper amplitude and duration to a first temperature and quenched to form an amorphous state, and then is heated to a second temperature to obtain a crystalline phase-separated state; and
a pair of electrode layers;
wherein the eutectic memory layer is located between the pair of electrode layers, when the eutectic memory layer is heated to the first temperature by the pair of electrode layers and rapidly cooled to an amorphous state, the eutectic memory layer has a first resistance; when the eutectic memory layer is heated to the second temperature by the pair of electrode layers and cooled to a phase-separated crystalline state, the eutectic memory layer has a second resistance, and the first resistance is higher than the second resistance by more than 10 times.

15. The eutectic memory according to claim 14, wherein material of the eutectic memory layer is eutectic alloy mainly containing germanium, or the eutectic alloy mainly containing silicon, or the eutectic alloy mainly containing carbon.

16. The eutectic memory according to claim 15, wherein the material of the eutectic memory layer comprises metal that form eutectic with germanium, and the metal is selected from the group consisting of aluminum, copper, tin, antimony, gold, and silver and the combination thereof.

17. The eutectic memory according to claim 15, wherein the material of the eutectic memory layer comprises metal that form eutectic with silicon, and the metal is selected from the group consisting of aluminum, copper, tin, antimony, gold, and silver and the combination thereof.

18. The eutectic memory according to claim 15, wherein the material of the eutectic memory layer comprises metal that form eutectic with carbon, and the metal is selected from the group consisting of copper, antimony, gold, and silver and the combination thereof.

19. The eutectic memory according to claim 15, wherein the material of the eutectic memory layer further comprises an additive element, the additive element is selected from the group consisting of titanium, oxygen, nitrogen, boron, and carbon; or nitride thereof, or oxide thereof.

20. The eutectic memory according to claim 15, wherein the eutectic memory layer contains germanium between 50 at % and 75 at %.

21. The eutectic memory according to claim 15, wherein the eutectic memory layer contains silicon between 15 at % and 75 at %.

22. The eutectic memory according to claim 15, wherein the eutectic memory layer contains carbon between 5 at % and 20 at %.

23. The eutectic memory according to claim 14, wherein the temperature of eutectic memory layer in between the pair of electrode layers is positively correlated with the current density passing through.

24. The eutectic memory according to claim 14, wherein material of the pair of electrode layers is selected from the group consisting of titanium (Ti), titanium tungsten (TiW), titanium nitride (TiN), tungsten nitride (WN), tantalum nitride (TaN), and aluminum titanium nitride (TiAlN).

25. The eutectic memory according to claim 14, wherein the pair of electrode layers comprises a top electrode layer and a bottom electrode layer.

26. The eutectic memory according to claim 14, wherein the pair of electrode layers comprises a left electrode layer and a right electrode layer.
